(19) United States
(12) Patent Application Publication
(10) Pub. No.: US 2024/0324397 A1
(43) Pub. Date: Sep. 26, 2024

(54) DISPLAY DEVICE AND METHOD OF MANUFACTURING THE SAME

(71) Applicant: Samsung Display Co., LTD., Yongin-si (KR)

(72) Inventors: Heemin PARK, Yongin-si (KR); Arong KIM, Yongin-si (KR); Youngmin MOON, Yongin-si (KR)

(21) Appl. No.: 18/438,698

(22) Filed: Feb. 12, 2024

(30) Foreign Application Priority Data
Mar. 24, 2023 (KR) 10-2023-0039225
May 19, 2023 (KR) 10-2023-0065234

(51) Int. Cl. H10K 59/80; H10K 59/12; H10K 59/122; H10K 59/124; H10K 59/131; H10K 71/60; H10K 102/00

(52) U.S. Cl. CPC H10K 59/80522; H10K 59/1201; H10K 59/122; H10K 59/124; H10K 71/60; H10K 59/131; H10K 2102/351

(57) ABSTRACT

A display device includes a substrate, a gate insulating layer, an auxiliary electrode extending in a first direction in a plan view parallel to the substrate and including a first portion and a second portion, the first portion having a first thickness in a second direction crossing the first direction, and the second portion having a second thickness in the second direction, an inorganic insulating layer defining a first opening exposing a portion of the second portion, an organic insulating layer defining a second opening exposing a portion of the second portion, an intermediate layer disposed on the organic insulating layer and defining a third opening exposing a portion of the second portion, and an opposite electrode disposed on the intermediate layer and contacting upper and side surfaces of the auxiliary electrode. The second thickness of the second portion is less than the first thickness of the first portion.

This application claims priority to Korean Patent Application No. 10-2023-0039225, filed on Mar. 24, 2023, and Korean Patent Application No. 10-2023-0065234, filed on May 19, 2023, and all the benefits accruing therefrom under 35 U.S.C. § 119, the contents of which in their entirety is herein incorporated by reference.

### BACKGROUND

### 1. Field

Embodiments relate to a display device and a method of manufacturing the display device.

### 2. Description of the Related Art

Display devices visually display data. Display devices may provide images by light-emitting diodes. As a usage of display devices is being diversified, various designs for improving quality of display devices are being attempted.

### SUMMARY

Embodiments include a display device with improved reliability and quality and a method of manufacturing the display device. However, this objective is only an example, and the scope of embodiments is not limited thereby.

Additional features will be set forth in part in the description which follows and, in part, will be apparent from the description, or may be learned by practice of the presented embodiments of the disclosure.

In an embodiment of the disclosure, a display device includes a substrate, a gate insulating layer disposed on the substrate, an auxiliary electrode disposed on the gate insulating layer, extending in a first direction in a plane parallel to a main plane of the substrate, and including a first portion and a second portion, the first portion having a first thickness in a second direction crossing the first direction in the plane, and the second portion having a second thickness in the second direction, an inorganic insulating layer disposed on the gate insulating layer and defining a first opening exposing at least a portion of the second portion of the auxiliary electrode, an organic insulating layer disposed on the inorganic insulating layer and defining a second opening exposing at least a portion of the second portion of the auxiliary electrode, an intermediate layer disposed on the organic insulating layer and defining a third opening exposing at least a portion of the second portion of the auxiliary electrode, and an opposite electrode disposed on the intermediate layer and being in contact with upper and side surfaces of the auxiliary electrode, where the second thickness of the second portion is less than the first thickness of the first portion.

In an embodiment, an area of the third opening of the intermediate layer may be greater than an area in which the auxiliary electrode is disposed.

In an embodiment, a size of the first opening of the inorganic insulating layer may be greater than a size of the second opening of the organic insulating layer.

In an embodiment, the size of the second opening of the organic insulating layer may be greater than a size of the third opening of the intermediate layer.

In an embodiment, the display device may further include a first thin-film transistor including a semiconductor layer disposed on the substrate, a gate electrode disposed on the semiconductor layer, and a source electrode and a drain electrode disposed on the gate electrode.

In an embodiment, the display device may further include an organic light-emitting diode including a pixel electrode disposed on the organic insulating layer, an intermediate layer disposed on the pixel electrode, and an opposite electrode disposed on the intermediate layer.

In an embodiment, the display device may further include a pixel-defining layer which is disposed on the pixel electrode and in which an opening exposing at least a portion of the pixel electrode is defined.

In an embodiment, the pixel-defining layer may define a fourth opening, through which at least a portion of the second portion of the auxiliary electrode is exposed.

In an embodiment, a size of the fourth opening of the pixel-defining layer may be greater than each of a size of the second opening of the organic insulating layer and a size of the third opening of the intermediate layer.

In an embodiment, the intermediate layer may include a third portion adjacent to the third opening, and a fourth portion spaced apart from the third opening, except for the third portion, and a thickness of the third portion in a direction perpendicular to the main plane of the substrate may be greater than a thickness of the fourth portion in a direction perpendicular to the main plane of the substrate.

In an embodiment of the disclosure, a method of manufacturing a display device includes forming a gate insulating layer on a substrate, forming an auxiliary electrode on the gate insulating layer, the auxiliary electrode extending in a first direction in a plane parallel to a main plane of the substrate, and including a first portion having a first thickness in a second direction crossing the first direction, and a second portion having a second thickness in the second direction, forming an inorganic insulating layer on the gate insulating layer, the inorganic insulating layer defining a first opening that exposes at least a portion of the second portion of the auxiliary electrode, forming an organic insulating layer on the inorganic insulating layer, the organic insulating layer defining a second opening that exposes at least a portion of the second portion of the auxiliary electrode, forming an intermediate layer on the organic insulating layer, the intermediate layer defining a third opening that exposes at least a portion of the second portion of the auxiliary electrode, and forming an opposite electrode on the intermediate layer, the opposite electrode being in contact with upper and side surfaces of the auxiliary electrode, where the second thickness of the second portion is less than the first thickness of the first portion.

In an embodiment, the method may further include continuously forming the intermediate layer on the organic insulating layer and the auxiliary electrode, generating heat by applying a pulse voltage to at least a portion of the second portion of the auxiliary electrode, and defining the third opening exposing the second portion of the auxiliary electrode by removing, using the heat, at least a portion of the intermediate layer disposed on the upper and side surfaces of the auxiliary electrode.

In an embodiment, a pulse width of the pulse voltage may be greater than or equal to about 1 microsecond (μs) and less than or equal to about 10 μs.

In an embodiment, an area of the third opening of the intermediate layer may be greater than an area in which the auxiliary electrode is disposed.

In an embodiment, a size of the first opening of the inorganic insulating layer may be greater than a size of the second opening of the organic insulating layer, and the size of the second opening of the organic insulating layer may be greater than a size of the third opening of the intermediate layer.

In an embodiment, the method may further include, before the forming the inorganic insulating layer, forming a first thin-film transistor including a semiconductor layer disposed on the substrate, a gate electrode disposed on the semiconductor layer, and a source electrode and a drain electrode disposed on the gate electrode.

In an embodiment, the method may further include, before the forming the intermediate layer, forming a pixel electrode on the organic insulating layer, and forming, on the pixel electrode, a pixel-defining layer in which an opening exposing at least a portion of the pixel electrode is defined.

In an embodiment, the pixel-defining layer may define a fourth opening, through which at least a portion of the second portion of the auxiliary electrode is exposed.

In an embodiment, the intermediate layer may include a third portion adjacent to the third opening, and a fourth opening spaced apart from the third opening except for the third opening, and a thickness of the third portion in a direction perpendicular to the main plane of the substrate is greater than a thickness of the fourth portion in a direction perpendicular to the main plane of the substrate.

### BRIEF DESCRIPTION OF THE DRAWINGS

The above and other features and advantages of illustrative embodiments of the disclosure will be more apparent from the following description taken in conjunction with the accompanying drawings, in which:

FIGS. 1 and 2 are perspective views each schematically illustrating an embodiment of a display device;

FIGS. 3 and 4 are equivalent circuit diagrams schematically illustrating an embodiment of a light-emitting diode corresponding to a sub-pixel of a display device, and a sub-pixel circuit electrically connected to the light-emitting diode;

FIG. 5 is a plan view schematically illustrating an embodiment of a display panel;

FIG. 6 is a plan view schematically illustrating an embodiment of a display panel.

FIG. 7 is an enlarged plan view schematically illustrating region A in FIG. 6;

FIG. 8 is a cross-sectional view schematically illustrating an embodiment of a display panel; and

FIGS. 9 to 16 are cross-sectional views schematically illustrating a method of manufacturing a display panel.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Hereinafter, embodiments will be described with reference to the accompanying drawings, where like reference numerals refer to like elements throughout and a repeated description thereof is omitted.

In an embodiment below, terms, such as “first” and “second,” are used herein merely to describe a variety of elements, but the elements are not limited by the terms. Such terms are used only for the purpose of distinguishing one element from another element.

In an embodiment below, an expression used in the singular encompasses the expression of the plural, unless it has a clearly different meaning in the context.

In an embodiment below, terms, such as “include” or “comprise,” may be construed to denote a certain characteristic or element, or a combination thereof, but may not be construed to exclude the existence of or a possibility of addition of one or more other characteristics, elements, or combinations thereof.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the disclosure is not limited thereto.

When an embodiment may be implemented differently, a predetermined process order may be performed differently from the described order. In an embodiment, two consecutively described processes may be performed substantially at the same time or performed in an order opposite to the described order.

In the disclosure, “A and/or B” means A or B, or A and B. In addition, “at least one of A and B” means A, B, or A and B.

It will be understood that when a layer, region, or element is also referred to as being “connected” to another layer, region, or element, it may be “directly connected” to the other layer, region, or element or/and may be “indirectly connected” to the other layer, region, or element with other layer, region, or element therebetween. In an embodiment, it will be understood that when a layer, region, or element is also referred to as being “electrically connected” to another layer, region, or element, it may be “directly electrically connected” to the other layer, region, or element or/and may be “indirectly electrically connected” to other layer, region, or element with other layer, region, or element therebetween.

The x-axis, the y-axis, and the z-axis are not limited to three axes of the quadrangular, e.g., rectangular coordinate system, and may be interpreted in a broader sense. In an embodiment, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

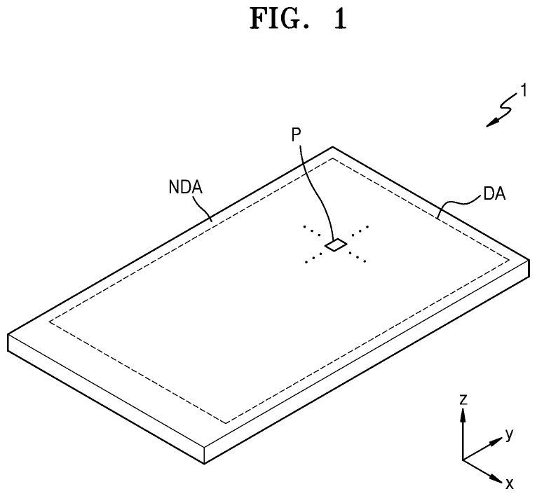

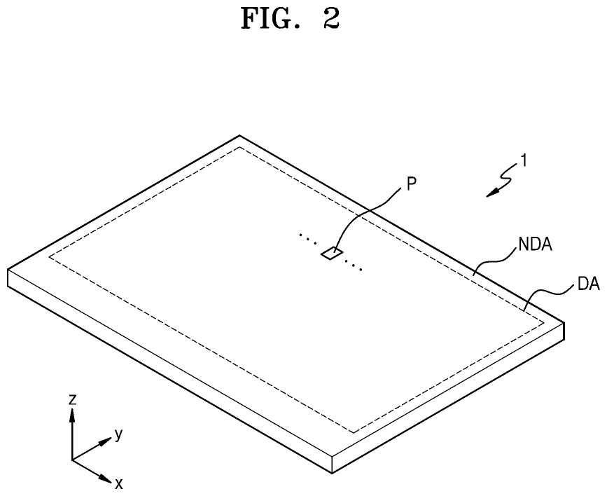

FIGS. 1 and 2 are perspective views schematically illustrating an embodiment of a display device 1.

Referring to FIGS. 1 and 2, the display device 1 may include a display area DA and a non-display area NDA disposed outside the display area DA. An image may be displayed in the display area DA through sub-pixels P arranged in the display area DA. The non-display area NDA is a non-display area, which is disposed outside the display area DA and in which an image is not displayed, and may surround an entirety of the display area DA. A driver or the like for providing an electrical signal or power to the display area DA may be disposed in the non-display area NDA. A pad, which is an area to which an electronic element or a printed circuit board may be connected, may be disposed in the non-display area NDA.

FIG. 1 shows an embodiment in which the display area DA has a polygonal shape (e.g., a quadrangle) of which a length in an x direction is less than a length in a y direction. However, in another embodiment, FIG. 2 shows another embodiment in which the display area DA has a polygonal shape (e.g., a quadrangle) of which the length in the y direction is less than the length in the x direction. Although the display area DA has an approximately quadrangular shape in FIGS. 1 and 2, the disclosure is not limited thereto. In another embodiment, the display area DA may be an N-gon (N is a natural number greater than or equal to 3), or may have various shapes, such as a circle or an ellipse. In FIGS. 1 and 2, a corner portion of the display area DA has a shape that includes a vertex at which two straight lines meet. However, in another embodiment, the display area DA may have a polygonal shape of which a corner portion is round.

Although it is described below that the display device 1 is an electronic device as a smartphone, for convenience of description, the display device 1 of embodiments is not limited thereto. The display device 1 may be applied to not only portable electronic devices, such as mobile phones, smartphones, tablet personal computers, mobile communication terminals, electronic notebooks, electronic books, portable multimedia players (“PMPs”), navigations, or ultra mobile personal computers (“UMPCs”), but also various products, such as televisions, laptops, monitors, billboards, or Internet of Things (“IoT”). In addition, the display device 1 in an embodiment may be applied to wearable devices, such as smart watches, watch phones, glasses-type displays, or head-mounted displays (HMDs). In addition, the display device 1 in an embodiment may be applied to instrument panels of vehicles, center information displays (“CIDs”) arranged on center fascias or dashboards of vehicles, room mirror displays with which side mirrors of vehicles are replaced, and display screens arranged on the rear surfaces of front seats as an entertainment for back seats of vehicles.

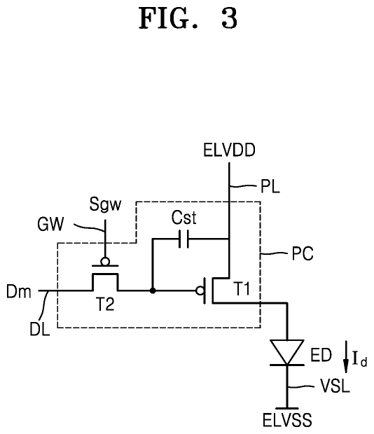

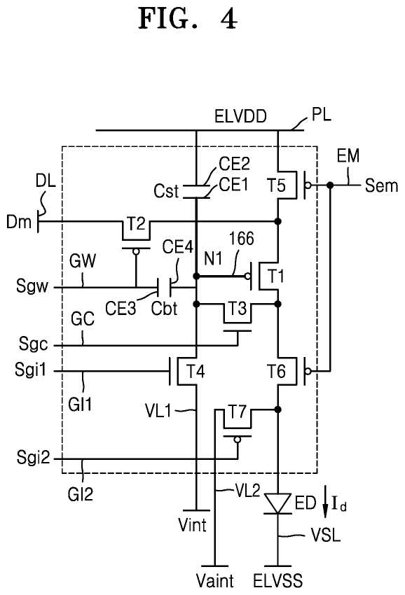

FIGS. 3 and 4 are equivalent circuit diagrams schematically illustrating an embodiment of a light-emitting diode ED corresponding to a sub-pixel of a display device, and a sub-pixel circuit PC electrically connected to the light-emitting diode.

Referring to FIG. 3, the light-emitting diode ED may be electrically connected to the sub-pixel circuit PC, and the sub-pixel circuit PC may include a first transistor T1, a second transistor T2, and a storage capacitor Cst. A sub-pixel electrode (e.g., an anode) of the light-emitting diode ED may be electrically connected to the first transistor T1, and an opposite electrode (e.g., a cathode) of the light-emitting diode ED may be electrically connected to an auxiliary line VSL and may receive a voltage corresponding to a common voltage ELVSS via the auxiliary line VSL.

The second transistor T2 may transmit a data signal Dm received via a data line DL to the first transistor T1 in response to a scan signal Sgw received via a scan line GW.

The storage capacitor Cst may be connected to the second transistor T2 and the driving voltage line PL and may store a voltage corresponding to a voltage difference between a voltage received from the second transistor T2 and the driving voltage ELVDD supplied to the driving voltage line PL.

The first transistor T1 may be connected to the driving voltage line PL and the storage capacitor Cst and may control a driving current Id in response to the voltage value stored in the storage capacitor Cst, the driving current Id flowing in the light-emitting diode ED from the driving voltage line PL. The light-emitting diode ED may emit light having a luminance according to the driving current Id.

In FIG. 3, the sub-pixel circuit PC includes two transistors and one storage thin-film transistor. However, the disclosure is not limited thereto.

Referring to FIG. 4, the sub-pixel circuit PC may include seven transistors and two capacitors.

The sub-pixel circuit PC may include first to seventh transistors T1, T2, T3, T4, T5, T6, and T7, a storage capacitor Cst, and a boost capacitor Cbt. In another embodiment, the sub-pixel circuit PC may not include the boost capacitor Cbt. The sub-pixel electrode (e.g., the anode) of the light-emitting diode ED may be electrically connected to the first transistor T1 via the sixth transistors T6, and the opposite electrode (e.g., the cathode) of the light-emitting diode ED may be electrically connected to the auxiliary line VSL and may receive the voltage corresponding to the common voltage ELVSS via the auxiliary line VSL.

Some of the first to seventh transistors T1, T2, T3, T4, T5, T6, and T7 are n-channel metal-oxide-semiconductor field-effect transistors (“n-channel MOSFETs”; “NMOSs”), and the other transistors may be p-channel MOSFETs (“PMOSs”). In an embodiment, as shown in FIG. 4, the third and fourth transistors T3 and T4 may be NMOSs, and the other transistors may be PMOSs. In an embodiment, the third and fourth transistors T3 and T4 may be NMOSs including an oxide-based semiconductor material, and the other transistors may be PMOSs including a silicon-based semiconductor material. In another embodiment, the third, fourth, and seventh transistors T3, T4, and T7 may be NMOSs, and the other transistors may be PMOSs, for example.

The first to seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The sub-pixel circuit PC may be electrically connected to voltage lines, e.g., the driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a first electrode (e.g., an anode) of the light-emitting diode ED via the sixth transistor T6. One of the first electrode and the second electrode of the first transistor T1 may be a source electrode, and the other electrode may be a drain electrode. The first transistor T1 may supply the driving current Id to the light-emitting diode ED in response to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be electrically connected to the driving voltage line PL via the fifth transistor T5 and connected to the first electrode of the first transistor T1. One of the first electrode and the second electrode of the second transistor T2 may be a source electrode, and the other electrode may be a drain electrode. The second transistor T2 may be turned on in response to the scan signal Sgw received via the scan line GW and perform a switching operation for transmitting the data signal Dm received via the data line DL to the first electrode of the first transistor T1.

The third transistor T3 may be a compensation transistor for compensating a threshold voltage of the first transistor T1. A third gate electrode of the third transistor T3 may be connected to the compensation gate line GC. A first electrode of the third transistor t3 may be connected via a node connection line 166 to the lower electrode CE1 of the storage capacitor Cst and the first gate electrode of the first transistor T1. The first electrode of the third transistor T3 may be connected to the fourth transistor T4. A second electrode of the third transistor T3 may be electrically connected via the sixth transistor T6 to the first electrode (e.g., the anode) of the light-emitting diode ED and connected to the second electrode of the first transistor T1. One of the first electrode and the second electrode of the third transistor T3 may be a source electrode, and the other electrode may be a drain electrode.

The third transistor T3 may be turned on in response to a compensation signal Sgc received via the compensation gate line GC and electrically connected to the first gate electrode and the second electrode (e.g., the drain electrode) of the first transistor T1, to diode-connect the first transistor T1.

The fourth transistor T4 may be an initialization transistor for initializing the first gate electrode of the first transistor T1. A fourth gate electrode of the fourth transistor T4 may be connected to the first initialization gate line Gil. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other electrode may be a drain electrode. The fourth transistor T4 may be turned on in response to a first initialization signal Sgi1 received via the first initialization gate line Gil, and may perform an initialization operation for transferring a first initialization voltage Vint to the first gate electrode of the first transistor T1 and initializing a voltage of the first gate electrode of the first transistor T1.

The fifth transistor T5 may be an operation control transistor. A fifth gate electrode of the fifth transistor T5 may be connected to the emission control line EM, a first electrode of the fifth transistor T5 may be connected to the driving voltage line PL, and a second electrode of the fifth transistor T5 may be electrically connected to the first electrode of the first transistor T1 and the second electrode of the second transistor T2. One of the first electrode and the second electrode of the fifth transistor T5 may be a source electrode, and the other electrode may be a drain electrode.

The sixth transistor T6 may be an emission control transistor. A sixth gate electrode of the sixth transistor T6 may be electrically connected to the emission control line EM, a first electrode of the sixth transistor T6 may be connected to the secondo electrode of the first transistor T1 and the second electrode of the third transistor T3, and a second electrode of the sixth transistor T6 may be electrically connected to a second electrode of the seventh transistor T7 and the first electrode (e.g., the anode) of the light-emitting diode ED. One of the first electrode and the second electrode of the sixth transistor T6 may be a source electrode, and the other electrode may be a drain electrode.

The fifth transistor T5 and the sixth transistor T6 may be simultaneously turned on in response to an emission control signal Sem received via the emission control line EM, so that the driving voltage ELVDD is transferred to the light-emitting diode ED and the driving current Id flows through the light-emitting diode ED.

The seventh transistor T7 may be a second initialization transistor for initializing the first electrode (e.g., the anode) of the light-emitting diode ED. A seventh gate electrode of the seventh transistor T7 may be connected to the second initialization gate line GI2. A first electrode of the seventh transistor T7 may be connected to the second initialization voltage line VL2. The second electrode of the seventh transistor T7 may be connected to the second electrode of the sixth transistor T6 and the first electrode (e.g., the anode) of the light-emitting diode ED. The seventh transistor T7 may be turned on in response to a second initialization signal Sgi2 received via the second initialization gate line GI2, and transfer a second initialization voltage Vaint to the first electrode (e.g., the anode) of the light-emitting diode ED, to initialize the first electrode of the light-emitting diode ED.

In some embodiments, the second initialization voltage line VL2 may be a next scan line. In an embodiment, the second initialization gate line GI2 connected to the seventh transistor T7 of the sub-pixel circuit PC, the second initialization gate line GI2 being disposed in an i-th (i is a natural number) row, may correspond to a scan line of the sub-pixel circuit PC disposed in an (i+1)th row, for example. In another embodiment, the second initialization voltage line VL2 may be the emission control line EM. In an embodiment, the emission control line EM may be electrically connected to the fifth to seventh transistors T5, T6, and T7, for example.

The storage capacitor Cst may include the lower electrode CE1 and the upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may store charges corresponding to a voltage difference between a voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. When the scan signal Sgw received via the scan line GW is turned off, the boost capacitor may increase a voltage of a first node N1, and when the voltage of the first node N1 increases, a black gradation may be vividly expressed.

The first node N1 may be an area in which the first gate electrode of the first transistor T1, the first electrode of the third transistor T3, the second electrode of the fourth transistor T4, and the fourth electrode CE4 of the boost capacitor Cbt contact each other.

In an embodiment, FIG. 4 illustrates that the third and fourth transistors T3 and T4 are NMOSs, and the first, second, and fifth to seventh transistors T1, T2, T5, T6, and T7 are PMOSs. The first transistor T1, which directly affects a brightness of a display device on which an image is displayed, includes a semiconductor layer including a highly reliable polycrystalline silicon, so that a high-resolution display device may be implemented.

In FIG. 4, some transistors are NMOSs, and the other transistors are PMOSs. However, the disclosure is not limited thereto. In another embodiment, the sub-pixel circuit PC may include three transistors, which are all NMOSs, and various modifications may be made.

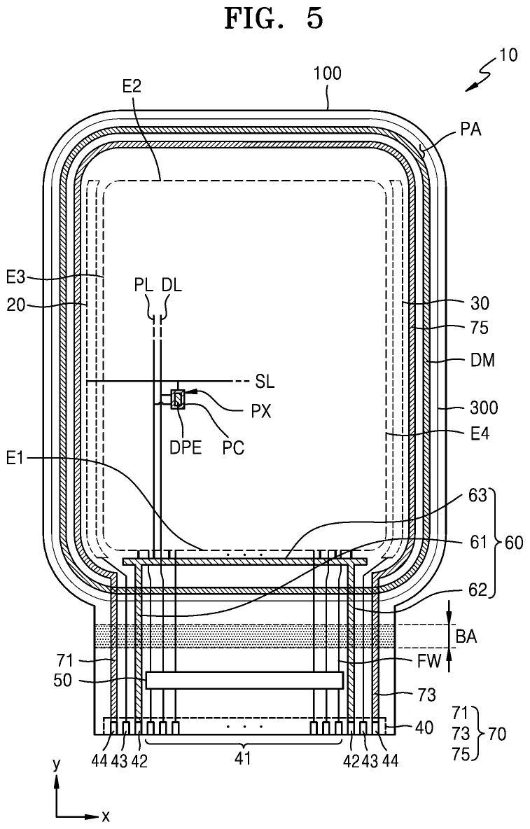

FIG. 5 is a plan view schematically illustrating an embodiment of a display panel 10.

Referring to FIG. 5, the display panel may include first and second scan driving units 20 and 30, a terminal unit 40, a data driving unit 50, and a power supply line, which are disposed on a substrate 100. The power supply line may include a driving voltage supply line 60 and a common voltage supply line 70.

The substrate 100 may include a bending area BA in which a portion of a peripheral area PA is bent. When the peripheral area PA that extends is folded with respect to the bending area BA, the peripheral area PA may partially overlap the display area DA. Through this structure, the peripheral area PA that extends may not be visible to a user, and even when the peripheral area PA is visible, a visible area may be minimized.

A plurality of sub-pixels PX may be arranged in the display area DA. Each of the sub-pixels PX may be implemented by a display element DPE, such as an organic light-emitting diode. In an embodiment, each of the sub-pixels PX may emit red, green, blue, or white light, for example.

Each of the sub-pixel circuits PC for driving the sub-pixels PX on the display area DA may be connected to a signal line or a voltage line for controlling an on/off and a luminance of the display element, e.g., a light-emitting diode. In an embodiment, FIG. 5 illustrates, as signal lines, a scan line SL extending in a first direction (e.g., an x direction), and a data line DL extending in a second direction (e.g., a y direction), and illustrates the driving voltage line as a voltage line, for example.

Each of the sub-pixel circuits PC for driving the sub-pixels may be electrically connected to outer circuits arranged in the peripheral area PA. In the peripheral area PA, the first and second scan driving units 20 and 30, the terminal unit 40, the data driving unit 50, the driving voltage supply line 60, and the common voltage supply line 70 may be arranged.

The first scan driving unit 20 and the second scan driving unit 30 may generate and transmit a scan signal to each of the sub-pixel circuits PC via the scan line SL. In an embodiment, one of the first scan driving unit 20 and the second driving unit 30 may apply an emission control signal to each of the sub-pixel circuits PC via an emission control line. In an embodiment, a structure in which the first and second scan driving units 20 and 30 are arranged at opposite sides of the display area DA is shown. However, in another embodiment, the scan driving unit may be disposed only at one side of the display area DA. The second scan driving unit 30 may be disposed to be symmetrical to the first scan driving unit 20 with respect to the display area DA.

The data driving unit 50 may generate and transmit a data signal to each of the sub-pixel circuits PC via the data line DL and a wiring FW. The data driving unit 50 may be disposed at one side of the display area DA, and may be disposed in the peripheral area PA that extends from a lower side of the display area DA in a lower direction (e.g., a y direction). In FIG. 5, the data driving unit 50 is disposed on the substrate 100. However, in another embodiment, the data driving unit 50 may be provided on a flexible printed circuit board connected to the terminal unit 40.

The terminal unit 40 may be disposed at one end of the substrate 100, and may include a plurality of terminals 41, 42, 43, and 44. The terminal unit 40 may be exposed without being covered by an insulating layer, and may be electrically connected to a controller, such as a printed circuit board or an integrated circuit (“IC”) chip. Control signals of the controller may be respectively provided via the terminal unit 40 to the first scan driving unit 20, the second scan driving unit 30, the data driving unit 50, the driving voltage supply line 60, and the common voltage supply line 70.

The driving voltage supply line 60 may be disposed in the peripheral area PA. The driving voltage supply line 60 may provide the driving voltage ELVDD to each of the sub-pixels PX. In an embodiment, the driving voltage supply line 60 may include a first driving voltage supply line 61, a second driving voltage supply line 62, and a third driving voltage supply line 63. The third driving voltage supply line 63 may extend in the first direction (e.g., the x direction), and the first and second driving voltage supply lines 61 and 62 may each extend in the second direction (e.g., the y direction). In an embodiment, the third driving voltage supply line 63 may be disposed along a first edge E1 of the display area DA, for example. In an embodiment, the first driving voltage supply line 61, the second driving voltage supply line 62, and the third driving voltage supply line 63 may be unitarily provided as a single body. In an embodiment, the driving voltage supply line 60 may have a “π” (“PI”) shape as an integral body, for example. However, the disclosure is not limited thereto.

The driving voltage supply line 60 may be disposed in the peripheral area PA and connected to a plurality of driving voltage lines PL each extending to the display area DA in the second direction (e.g., the y direction). In an embodiment, the third driving voltage supply line 63 may be connected to the driving voltage line PL crossing the display area DA in the second direction (e.g., the y direction), for example.

The common voltage supply line 70 may be disposed in the peripheral area PA and may provide the common voltage ELVSS to each of the sub-pixels PX. The common voltage supply line 70 may include a first common voltage supply line 71 and a second common voltage supply line 73, which are arranged adjacent to the first edge E1. Each of the first common voltage supply line 71 and the second common voltage supply line 73 may extend in the second direction (e.g., the y direction). In addition, the first common voltage supply line 71 and the second common voltage supply line 73 may be arranged to be spaced apart from each other in the first direction (e.g., the x direction) crossing the second direction (e.g., the y direction). The first common voltage supply line 71 and the second common voltage supply line 73 may be arranged at opposite sides of the first edge E1 of the display area DA, respectively. However, the disclosure is not limited thereto. The common voltage supply line 70 may further include a third common voltage supply line between the first common voltage supply line 71 and the second common voltage supply line 73. When the common voltage supply line 70 includes a third common voltage supply line between the first common voltage supply line 71 and the second common voltage supply line 73, a current density may be reduced and heating may be suppressed compared to a case in which only the first common voltage supply line 71 and the second common voltage supply line 73 are provided.

The first common voltage supply line 71 and the second common voltage supply line 73 may be connected to a body unit 75 extending along a second edge E2, a third edge E3, and a fourth edge E4 of the display area DA. In an embodiment, the first common voltage supply line 71, the second common voltage supply line 73, and the body unit 75 may be unitarily provided as a single body.

A dam DM may be disposed in the peripheral area PA. The dam DM may be disposed to surround an outer boundary of the display area DA. The dam DM may be disposed outside the common voltage supply line 70 or may be disposed to partially overlap the common voltage supply line 70.

The encapsulation layer 300 may be disposed in the display area DA to cover an area of the sub-pixel PX, and a portion of the encapsulation layer 300 may extend to the peripheral area PA. The encapsulation layer 300 has a multi-layered structure including at least one organic encapsulation layer and at least one inorganic encapsulation layer, and the dam DM may prevent a material for forming the organic encapsulation layer included in the encapsulation layer from being diffused toward an edge of the substrate 100, and limit a formation location of the organic encapsulation layer.

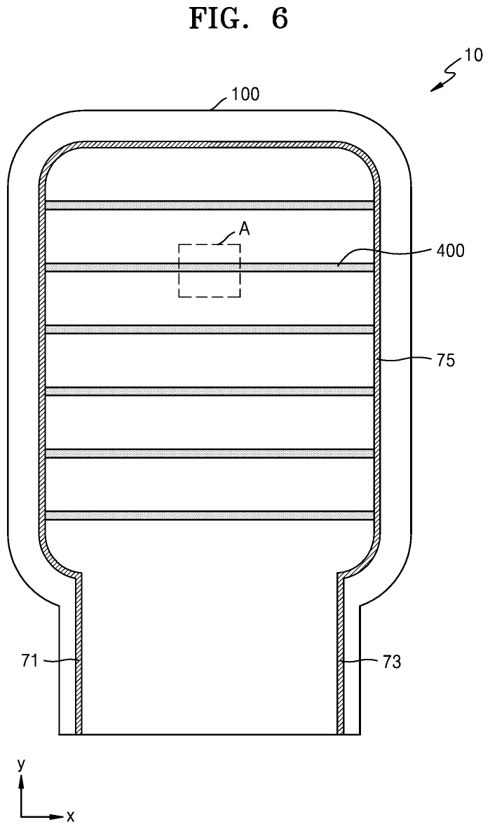

FIG. 6 is a plan view schematically illustrating the display panel 10. In an embodiment, the common voltage supply line 70 and the auxiliary electrode 400 are shown, for example.

Referring to FIG. 6, as described above, the common voltage supply line 70 may include the first common voltage supply line 71, the second common voltage supply line 73, and the body unit 75. The first common voltage supply line 71 and the second common voltage supply line 73 may be arranged to extend in the second direction (e.g., the y direction or a −y direction), and the first common voltage supply line 71 and the second common voltage supply line 73 may be arranged to be spaced apart from each other in the first direction (e.g., the x direction or the −x direction). The first common voltage supply line 71 and the second common voltage supply line 73 may be electrically connected by the body unit 75. The common voltage supply line 70 may be disposed in the peripheral area PA (refer to FIG. 5) and may provide the common voltage ELVSS to each of the sub-pixels PX (refer to FIG. 5).

As a size of the display panel 10 has increased, in order to improve a voltage drop phenomenon in which a luminance of a central portion of the display panel 10 decreases, the auxiliary electrode 400 electrically connected to the common voltage may be disposed in an active area of the display panel 10, thereby reducing a distance between the common voltage supply line 70 and the sub-pixel circuit PC (refer to FIG. 3).

The auxiliary electrode 400 may be disposed to extend in the first direction (e.g., the x direction or the −x direction). The auxiliary electrodes 400 may be disposed to be spaced apart from each other in the second direction (e.g., the y direction or the −y direction). The auxiliary electrode 400 may be electrically connected to the body unit 75 of the common voltage supply line 70. The common voltage ELVSS may be supplied to the sub-pixel circuits PC (refer to FIG. 3) through the through the body unit 75 and the auxiliary electrode 400, so that the distance between the common voltage supply line 70 and the sub-pixel circuit PC (refer to FIG. 3) may be reduced, and a voltage drop phenomenon may be improved, and thus, the luminance of the central portion of the display panel 10 may be improved. However, the disclosure is not limited thereto. In another embodiment, the auxiliary electrode 400 may extend in the second direction (e.g., the y direction or the −y direction), and the auxiliary electrodes 400 may be disposed to be spaced apart from each other in the first direction (e.g., the x direction or the −x direction). The auxiliary electrodes 400 each extending in the second direction (e.g., the y direction or the −y direction) may be electrically connected to the body unit 75 extending in the first direction (e.g., the x direction or the −x direction).

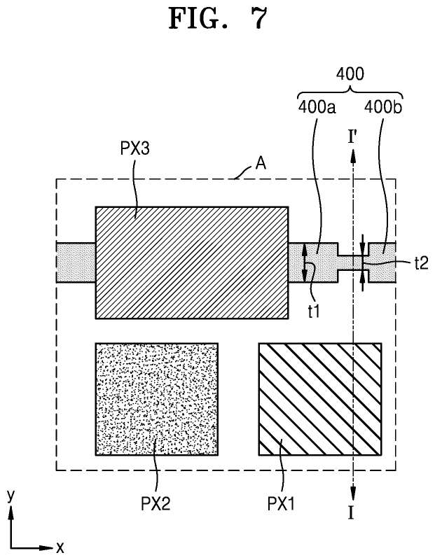

FIG. 7 is an enlarged plan view schematically illustrating region A in FIG. 6. Specifically, FIG. 7 schematically illustrates a plan view of an auxiliary electrode and sub-pixels arranged to be adjacent to the auxiliary electrode.

Referring to FIG. 7, a sub-pixel unit may be disposed to overlap the auxiliary electrode 400 or to be adjacent to the auxiliary electrode 400. The sub-pixel unit may include a first sub-pixel PX1, a second sub-pixel PX2, and a third sub-pixel PX3. The first sub-pixel PX1, the second sub-pixel PX2, and the third sub-pixel PX3 may emit light of different colors from each other. In an embodiment, the first sub-pixel PX1 may emit red light, and the second sub-pixel PX2 may emit green light, for example. In addition, the third sub-pixel PX3 may emit blue light. The first sub-pixel PX1 and the second sub-pixel PX2 may be arranged to be spaced apart from the auxiliary electrode 400. Specifically, the first sub-pixel PX1 and the second sub-pixel PX2 may be arranged to be spaced apart from the auxiliary electrode 400 in the −y direction. The third sub-pixel PX3 may be disposed to overlap the auxiliary electrode 400.

The auxiliary electrode 400 may be disposed to extend in the first direction (e.g., the x direction or the −x direction). The auxiliary electrode 400 may include a first portion 400a and a second portion 400b. Although not shown, in a plan view of the display panel 10 (refer to FIG. 6), the second portions 400b of the auxiliary electrode 400 may be disposed to be spaced apart from each other in the first direction (e.g., the x direction or the −x direction) with the first portion 400a of the auxiliary electrode 400 therebetween. However, the disclosure is not limited thereto. The auxiliary electrode 400 may be disposed to extend in the second direction (e.g., the y direction or the −y direction), and in this case, the second portions 400b of the auxiliary electrode 400 may be disposed to be spaced apart from each other in the second direction (e.g., the y direction or the −y direction) with the first portion 400a of the auxiliary electrode 400 therebetween.

The first portion 400a of the auxiliary electrode 400 may have a first thickness t1 in the second direction (e.g., the y direction or the −y direction). The second portion 400b of the auxiliary electrode 400 may have a second thickness t2 in the second direction (e.g., the y direction or the −y direction). The second thickness t2 of the second portion 400b of the auxiliary electrode 400 may be less than the first thickness t1 of the first portion 400a of the auxiliary electrode 400. In other words, the first thickness t1 of the first portion 400a of the auxiliary electrode 400 may be greater than the second thickness t2 of the second portion 400b of the auxiliary electrode 400.

When the second thickness t2 of the second portion 400b of the auxiliary electrode 400 is provided to be less than the first thickness t1 of the first portion 400a of the auxiliary electrode 400, a wiring resistance of the second portion 400b of the auxiliary electrode 400 may be greater than a wiring resistance of the first portion 400a of the auxiliary electrode 400. When a pulse voltage is applied to the second portion 400b having a thickness less than that of the first portion 400a and having a relatively large wiring resistance, heat may be selectively generated in the second portion 400b of the auxiliary electrode 400 due to Joule heating. Because heat is selectively generated in only the second portion 400b of the auxiliary electrode 400, an ambient temperature does not rise, so that the pixel may not be damaged.

When the pulse voltage is applied to the second portion 400b of the auxiliary electrode 400 and heat is generated due to Joule heating, at least a portion of an intermediate layer 212 disposed on the second portion 400b of the auxiliary electrode 400 may be removed. In addition, due to the heat generated in the second portion 400b of the auxiliary electrode 400, at least a portion of the intermediate layer 212 disposed on the first portion 400a of the auxiliary electrode 400 adjacent to the second portion 400b may also be removed. When the at least a portion of the intermediate layer 212 disposed on the second portion 400b and the first portion 400a of the auxiliary electrode 400, the first portion being adjacent to the second portion 400b is removed, at least a portion of the second portion 400b and the first portion 400a of the auxiliary electrode 400 may be exposed. In this case, an area obtained by removing the intermediate layer 212 adjacent to the second portion 400b of the auxiliary electrode 400 may be larger than an area in which the second portion 400b of the auxiliary electrode 400 is exposed (or disposed). In other words, the second portion 400b of the auxiliary electrode 400 may be disposed inside an area obtained by removing the intermediate layer 212.

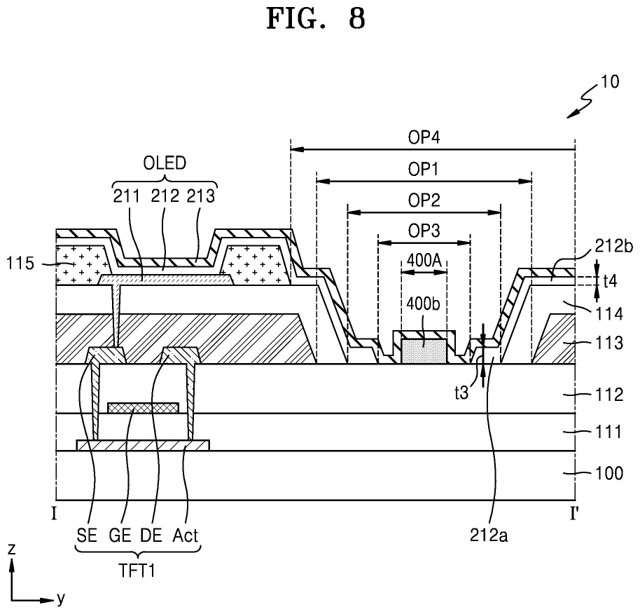

When heat is generated by applying a pulse voltage to the second portion 400b of the auxiliary electrode 400, at least the portion of the intermediate layer 212 disposed on the second portion 400b and the first portion 400a of the auxiliary electrode 400, the first portion 400a being adjacent to the second portion 400b, may be arranged by being pushed aside from the second portion 400b of the auxiliary electrode 400. In other words, a thickness of the intermediate layer 212 at a point where the area obtained by removing the intermediate layer 212 starts may be greater than a thickness of an adjacent intermediate layer 212. This is described in greater detail below with reference to FIG. 8.

When an auxiliary electrode having an undercut shape is disposed to be spaced apart from a display panel and, due to a difference in incidence angle between an intermediate layer and an opposite electrode, which are deposited on the auxiliary electrode having the undercut shape, the opposite electrode contacts the auxiliary electrode, because the difference in incidence angle is small, a degree of contact between the opposite electrode and the auxiliary electrode may be small, and a voltage drop phenomenon of the display panel may not be effectively improved.

In an embodiment, when a pulse voltage is applied to the second portion 400b of the auxiliary electrode 400 and heat is generated due to Joule heating, at least a portion of the intermediate layer 212 disposed on the second portion 400b of the auxiliary electrode 400 is removed so that the second portion 400b of the auxiliary electrode 400 is exposed, and thus, the opposite electrode 213 (refer to FIG. 8) may be disposed to contact the second portion 400b of the auxiliary electrode 400. Because the auxiliary electrode 400 is electrically connected to the common voltage supply lines 71, 73, and 75 (refer to FIG. 6) of the display panel 10 (refer to FIG. 6), a distance between the common voltage ELVSS and the sub-pixel circuit may be reduced, and a voltage drop phenomenon in the active area of the display panel 10 (refer to FIG. 6) may be improved, so that a luminance may be improved.

FIG. 8 is a cross-sectional view schematically illustrating the display panel 10. Specifically, FIG. 8 schematically illustrates a cross-sectional view of the display panel in FIG. 7, taken along line I-I′ in FIG. 7.

Referring to FIG. 7, the display panel 10 may include the substrate 100, inorganic insulating layers 111, 112, and 113, an organic insulating layer 114, a first thin-film transistor TFT1, the auxiliary electrode 400 (refer to FIG. 7), a pixel-defining layer 115, and an organic light-emitting diode OLED. In other words, on the display area of the display panel 10, the substrate 100, the inorganic insulating layer 111, 112, and 113, the organic insulating layer 114, the first thin-film transistor TFT1, the auxiliary electrode 400 (refer to FIG. 7), the pixel-defining layer 115, and the organic light-emitting diode OLED may be disposed.

Although not shown, the substrate 100 may include a first base layer, a first barrier layer, a second base layer, and a second barrier layer. In an embodiment, the first base layer, the first barrier layer, the second base layer, and the second barrier layer may be sequentially stacked in a thickness direction of the substrate 100.

At least one of the first base layer and the second base layer may include a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The first barrier layer and the second barrier layer are barrier layers for preventing permeation of external foreign substances and may be a layer or layers including an inorganic material, such as silicon nitride (SiNₓ), silicon oxide (SiO₂), and/or silicon oxynitride (SiON).

Although not shown, a buffer layer may be disposed on the substrate 100. The buffer layer may include an inorganic insulating material, such as SiNₓ, SiON, or SiO₂, and may be a layer or layers including the inorganic insulating material described above.

The inorganic insulating materials 111, 112, and 113 may be disposed on the buffer layer. The inorganic insulating layers 111, 112, and 113 may include a first gate insulating layer 111, a second gate insulating layer 112, and a first inorganic insulating layer 113.

The first thin-film transistor TFT1 may be disposed in the display area DA. The first thin-film transistor TFT1 may include a semiconductor layer Act, a gate electrode GE, a source electrode SE, and a drain electrode DE.

The semiconductor layer Act may be disposed on the substrate 100. The semiconductor layer Act may include polysilicon. In an alternative embodiment, the semiconductor layer Act may include amorphous silicon, an oxide semiconductor, an organic semiconductor, or the like. The semiconductor layer Act may include a channel region, a drain region, and a source region, the drain region and the source region being respectively arranged at opposite sides of the channel region.

The gate electrode GE may be disposed on the semiconductor layer Act. The gate electrode GE may overlap the channel region. The gate electrode GE may include a low-resistance metal material. The gate electrode GE may include a conductive material, including molybdenum (Mo), aluminum (Al), copper (Cu), and titanium (Ti), and may include a layer or layers including the material described above.

The first gate insulating layer 111 may be disposed between the semiconductor layer Act and the gate electrode GE. The first gate insulating layer 111 may include an inorganic insulating material, such as SiO₂, SiNx, SiON, aluminum oxide (Al₂O₃), titanium oxide (TiO₂), tantalum oxide (Ta₂O₅), hafnium oxide (HfO₂), or zinc oxide (ZnO).

The second gate insulating layer 112 may be disposed on the gate electrode GE. The second gate insulating layer 112 may be provided to cover the gate electrode GE. The second gate insulating layer 112 may include an inorganic insulating material, such as SiO₂, SiNx, SiON, Al₂O₃, TiO₂, Ta₂O₅, HfO₂, or ZnO.

Although not shown, an upper electrode of the storage capacitor Cst (refer to FIG. 4) may be disposed on the second gate insulating layer 112. The upper electrode may overlap the gate electrode GE disposed thereunder. In this case, the gate electrode GE and the upper electrode overlapping each other with the second gate insulating layer 112 therebetween may constitute the storage capacitor Cst (refer to FIG. 4). In other words, the gate electrode GE may function as a lower electrode of the storage capacitor Cst (refer to FIG. 4).

As described above, the storage capacitor Cst (refer to FIG. 4) and the first thin-film transistor TFT1 may be formed to overlap each other. However, the disclosure is not limited thereto. In an embodiment, the storage capacitor Cst (refer to FIG. 4) may be formed not to overlap the first thin-film transistor TFT1, for example. In other words, the lower electrode of the storage capacitor Cst (refer to FIG. 4) may be a separate element from the gate electrode GE of the first thin-film transistor TFT1 and may be provided to be spaced apart from the gate electrode GE of the first thin-film transistor TFT1.

The upper electrode may include aluminum (Al), platinum (Pt), palladium (Pd), silver (Ag), magnesium (Mg), gold (Au), nickel (Ni), neodymium (Nd), iridium (Ir), chrome (Cr), calcium (Ca), Mo, Ti, tungsten (W), and/or Cu, and may be a layer or layers of the materials described above.

The drain electrode DE and the source electrode SE may be disposed on the second gate insulating layer 112. The drain electrode DE and the source electrode SE may be connected to the semiconductor layer Act via contact holes provided in the first gate insulating layer 111 and the second gate insulating layer 112, respectively. Each of the drain electrode DE and the source electrode SE may include a material having good conductivity. Each of the drain electrode DE and the source electrode SE may include a conductive material, including Mo, Al, Cu, and Ti, and may include a layer or layers including the material described above. In an embodiment, each of the drain electrode DE and the source electrode SE may have a multi-layered structure of a Ti layer, an Al layer, and another Ti layer, for example.

The auxiliary electrode 400 (refer to FIG. 7) may be disposed on the second gate insulating layer 112. In FIG. 8, e.g., the second portion 400b of the auxiliary electrode 400 may be disposed on the second gate insulating layer 112. The auxiliary electrode 400 (refer to FIG. 7) may include a material through which current flows. In an embodiment, the auxiliary electrode 400 (refer to FIG. 7) may include a metal film (Mo or Al) or an oxide film (indium tin oxide (“ITO”) or indium zinc oxide (“IZO”). However, the disclosure is not limited thereto. In another embodiment, the auxiliary electrode 400 (refer to FIG. 7) may be formed in the same process in which the source electrode SE and the drain electrode are formed, and may include the same material as that of the source electrode SE and the drain electrode DE.

A first opening OP1, through which at least a portion of the second portion 400b of the auxiliary electrode 400 (refer to FIG. 7) is exposed, may be defined in the first inorganic insulating layer 113. In other words, the second portion 400b of the auxiliary electrode 400 (refer to FIG. 7) may be disposed in the first opening OP1 of the first inorganic insulating layer 113.

The first inorganic insulating layer 113 may be disposed on the second gate insulating layer 112. The first inorganic insulating layer 113 may include SiO₂, SiNₓ, SiON, Al₂O₃, TiO₂, Ta₂O₅, HfO₂, ZnO. The first inorganic insulating layer 113 may be a layer or layers including the inorganic insulating material described above.

The organic insulating layer 114 may be disposed on the first inorganic insulating layer 113. In FIG. 8, one organic insulating layer 114 is provided. However, the disclosure is not limited thereto. Two, three, or four organic insulating layers 114 may be provided.

A second opening OP2, through which at least a portion of the second portion 400b of the auxiliary electrode 400 (refer to FIG. 7) is exposed, may be defined in the organic insulating layer 114. In other words, the second portion 400b of the auxiliary electrode 400 (refer to FIG. 7) may be disposed in the second opening OP2 of the organic insulating layer 114.

The organic insulating layer 114 may include an organic insulating material, such as general-purpose polymers, such as poly(methyl methacrylate) (“PMMA”) or polystyrene (“PS”), polymer derivatives having a phenol-based group, acryl-based polymers, imide-based polymers, aryl ether-based polymers, amide-based polymers, fluorine-based polymers, p-xylene-based polymers, vinyl alcohol-based polymers, or any combinations thereof.

A light-emitting diode may be disposed on the organic insulating layer 114. In an embodiment, the organic light-emitting diode OLED may be disposed on the organic insulating layer 114, for example. In an alternative embodiment, although not shown, an inorganic light-emitting diode or the like may be disposed on the organic insulating layer 114.

The organic light-emitting diode OLED may emit one of red, green, or blue light, or one of red, green, blue, and white light. The organic light-emitting diode OLED may include a pixel electrode 211, an intermediate layer 212, and an opposite electrode 213.

The pixel electrode 211 may be disposed on the organic insulating layer 114. The pixel electrode 211 may be electrically connected to the source electrode SE or the drain electrode DE via contact holes defined in the organic insulating layer 114 and the first inorganic insulating layer 113. The pixel electrode 211 may include a conductive oxide, such as ITO, IZO, ZnO, In₂O₃, indium gallium oxide (“IGO”), or aluminum zinc oxide (“AZO”). In an embodiment, the pixel electrode 211 may include a reflective film including Ag, Mg, Al, Pt, Pd, Au, Ni, Nd, Ir, Cr, or any combinations thereof. In an embodiment, the pixel electrode 211 may further include a film including ITO, IZO, ZnO, or In₂O₃, on/under the reflective film described above. In an embodiment, the pixel electrode 211 may have a multi-layered structure of an ITO layer, an Ag layer, and another ITO layer, for example.

The pixel-defining layer 115 in which an opening exposing at least a portion of the pixel electrode 211 may be disposed on the pixel electrode 211. An emission area of light emitted from the organic light-emitting diode OLED may be defined by the opening defined in the pixel-defining layer 115. In an embodiment, a width of the opening may correspond to a width of the emission area, for example.

The pixel-defining layer 115 may include an organic insulating material. In an alternative embodiment, the pixel-defining layer 115 may include an inorganic insulating material, such as silicon nitride, silicon oxynitride, or silicon oxide. In an alternative embodiment, the pixel-defining layer 115 may include an organic insulating material and an inorganic insulating material. In an embodiment, the pixel-defining layer 115 may include a light-blocking material. The light-blocking material may include carbon black, carbon nanotubes, a resin or paste including black dye, metal particles, such as nickel, aluminum, molybdenum, or any alloys thereof, metal oxide particles (e.g., chrome oxide), or metal nitride particles (e.g., chrome nitride). When the pixel-defining layer 115 includes a light-blocking material, external reflection caused by metal structures disposed under the pixel-defining layer 115 may be reduced.

The intermediate layer 212 may be disposed on the pixel electrode 211. The intermediate layer 212 may include an emission layer, a first functional layer, and a second functional layer. The emission layer may be disposed in the opening of the pixel-defining layer 115. The emission layer may include a polymer or low-molecular weight organic material emitting light of a color.

The first functional layer may be disposed between the pixel electrode and the emission layer, and the second functional layer may be disposed between the emission layer and the opposite electrode. However, at least one of the first functional layer or the second functional layer may be omitted. A case in which the first functional layer and the second functional layer are each arranged is mainly described below.

The first functional layer may include a hole transport layer (“HTL”) and/or a hole injection layer (“HIL”). The second functional layer may include an electron transport layer (“ETL”) and/or an electron injection layer (“EIL”). The first functional layer and/or the second functional layer may be common layers formed to cover an entirety of the substrate 100 except for a portion of the auxiliary electrode 400 (refer to FIG. 7) to be described below, adjacent to the second portion 400b.

The opposite electrode 213 may be disposed on the intermediate layer 212. The opposite electrode 213 may include a conductive material having a relatively low work function. In an embodiment, the opposite electrode 213 may include a (semi-)transparent layer including Ag, Mg, Al, Pt, Pd, Au, Ni, Nd, Ir, Cr, Li, Ca, or any alloys thereof, for example. In an alternative embodiment, the opposite electrode 213 may further include a layer including ITO, IZO, ZnO, or In₂O₃, on the (semi-)transparent layer including the materials described above.

The intermediate layer 212 disposed to be adjacent to the second portion 400b of the auxiliary electrode 400 (refer to FIG. 7) may be disconnected. In an embodiment, a third opening OP3, through which at least a portion of the second portion 400b of the auxiliary electrode 400 (refer to FIG. 7) is exposed, may be defined in the intermediate layer 212, for example. In other words, the second portion 400b of the auxiliary electrode 400 (refer to FIG. 7) may be disposed in the third opening OP3 of the intermediate layer 212.

In an embodiment, a size of the first opening OP1 of the first inorganic insulating layer 113 may be greater than a size of the second opening OP2 of the organic insulating layer 114. The size of the first opening OP1 of the first inorganic insulating layer 113 may be greater than a size of the third opening OP3 of the intermediate layer 212. The size of the second opening OP2 of the organic insulating layer 114 may be greater than the size of the third opening OP3 of the intermediate layer 212.

The opposite electrode 213 may be continuously disposed on the substrate 100 to contact an upper surface and a side surface of the second portion 400b of the auxiliary electrode 400 (refer to FIG. 7). When at least a portion of the second portion 400b of the auxiliary electrode 400 (refer to FIG. 7) is exposed by the third opening OP3 of the intermediate layer 212, the opposite electrode 213 and the second portion 400b of the auxiliary electrode 400 (refer to FIG. 7) may be arranged to contact each other. Because the auxiliary electrode 400 (refer to FIG. 7) is electrically connected to the common voltage supply lines 71, 73, and 75 (refer to FIG. 6), the second portion 400b of the auxiliary electrode 400 (refer to FIG. 7) and the opposite electrode 213 may contact each other, so that a distance between the common voltage ELVSS and the sub-pixel circuit PC (refer to FIG. 3) may be reduced, and thus, a voltage drop phenomenon in the active area of the display panel 10 (refer to FIG. 6) and the luminance of the display panel may be improved.

A size of an area of the third opening OP3 of the intermediate layer 212 may be greater than a size of an area 400A in which the auxiliary electrode 400 (refer to FIG. 7) is disposed. When a pulse voltage is applied to the second portion 400b, heat may be generated due to Joule heating, and due to the heat, at least a portion of the intermediate layer 212 disposed on the second portion 400b may be removed. Due to the heat generated in the auxiliary electrode 400 (refer to FIG. 7) by Joule heating, at least a portion of the intermediate layer 212 disposed on the first portion 400a of the auxiliary electrode 400 (refer to FIG. 7) as well as the intermediate layer 212 disposed on the second portion 400b of the auxiliary electrode 400 (refer to FIG. 7) may be removed. In other words, by the third opening OP3 of the intermediate layer 212 defined due to heat generated in the auxiliary electrode 400 (refer to FIG. 7), not only the second portion 400b of the auxiliary electrode 400 (refer to FIG. 7), but also at least a portion of the first portion 400a of the auxiliary electrode 400 (refer to FIG. 7) may be exposed. The second portion 400b and at least a portion of the first portion 400a of the auxiliary electrode 400 (refer to FIG. 7) are exposed together, so that an area of contact between the opposite electrode 213 and the auxiliary electrode 400 (refer to FIG. 7) may increase, and a voltage drop phenomenon and luminance defects in the active area of the display panel 10 (refer to FIG. 6) may be efficiently improved.

Due to heat generated in the second portion 400b of the auxiliary electrode 400 (refer to FIG. 7) to which a pulse voltage is applied, at least a portion of the intermediate layer 212 disposed on the second portion 400b may be disposed to be pushed aside to a point where the third opening OP3 of the intermediate layer 212 starts. The intermediate layer 212 may include a third portion 212a disposed at a point where the third opening OP3 starts, and a fourth portion 212b disposed to be spaced apart from the third opening OP3 except for the third portion 212a. The third portion 212a may include at least a portion of the intermediate layer 212, at least the portion being disposed on the second portion 400b and then pushed aside to the third opening OP3 due to the heat generated in the auxiliary electrode 400 (refer to FIG. 7). The third portion 212a may have a third thickness t3 in a direction perpendicular to the substrate 100. The fourth portion 212b may have a fourth thickness t4 in a direction perpendicular to the substrate 100. The third thickness t3 of the third portion 212a may be greater than the fourth thickness t4 of the fourth portion 212b. However, the disclosure is not limited thereto.

A fourth opening OP4, through which at least a portion of the second portion 400b of the auxiliary electrode 400 (refer to FIG. 7) is exposed, may be defined in the pixel-defining layer 115. Because the fourth opening OP4 is defined in the pixel-defining layer 115, the second portion 400b of the auxiliary electrode 400 (refer to FIG. 7) may be exposed to contact the opposite electrode 213. A size of the fourth opening OP4 of the pixel-defining layer 115 may be greater than each of a size of the third opening OP3 of the intermediate layer 212 and the second opening OP2 of the organic insulating layer 114.

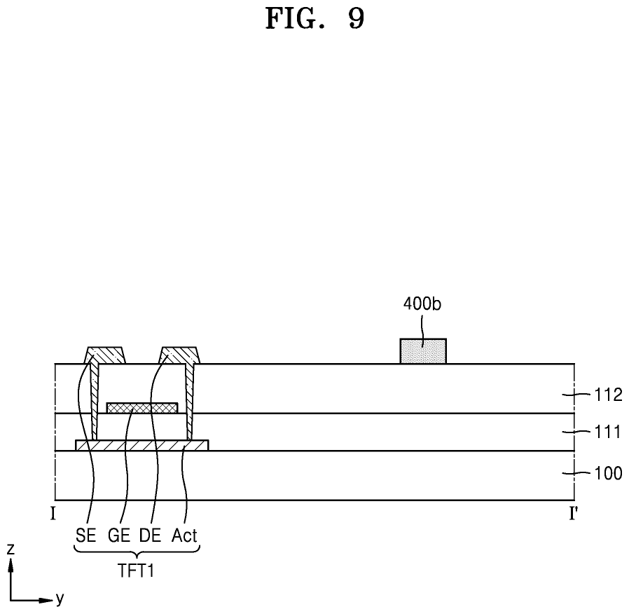

FIGS. 9 to 16 are cross-sectional views schematically illustrating a method of manufacturing a display panel.

Referring to FIG. 9, the first thin-film transistor TFT1 including the semiconductor layer Act, the gate electrode GE, the source electrode SE, and the drain electrode DE may be formed on the substrate 100. The first gate insulating layer 111 and the second gate insulating layer 112 may be formed on the substrate 100.

The auxiliary electrode 400 (refer to FIG. 7) may be formed on the second gate insulating layer 112. In an embodiment, the second portion 400b of the auxiliary electrode 400 (refer to FIG. 7) may be formed on the second gate insulating layer 112, for example. The auxiliary electrode 400 (refer to FIG. 7) may include a material through which current flows. In an embodiment, the auxiliary electrode 400 (refer to FIG. 7) may include a metal film (Mo or Al) or an oxide film (ITO or IZO), for example. However, the disclosure is not limited thereto. In another embodiment, the auxiliary electrode 400 (refer to FIG. 7) may be formed in the same process in which the source electrode SE and the drain electrode DE are formed, and may include the same material as that of the source electrode SE and the drain electrode DE.

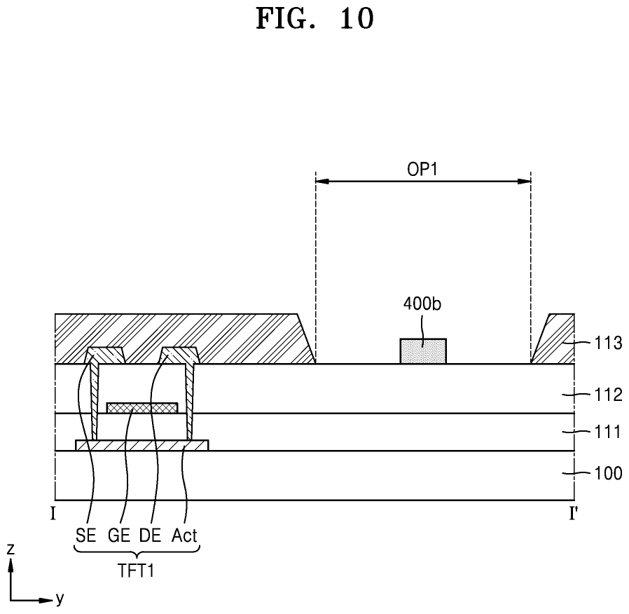

Referring to FIG. 10, the first inorganic insulating layer 113 may be formed on the second gate insulating layer 112. The first inorganic insulating layer 113 may include SiO₂, SiNₓ, SiON, Al₂O₃, TiO₂, Ta₂O₅, HfO₂, ZnO, etc. The first inorganic insulating layer 113 may be a layer or layers including the inorganic insulating materials described above.

The first opening OP1, through which at least a portion of the second portion 400b of the auxiliary electrode 400 is exposed, may be defined in the first inorganic insulating layer 113. In other words, the second portion 400b of the auxiliary electrode 400 may be disposed in the first opening OP1 of the first inorganic insulating layer 113. The first opening OP1 of the first inorganic insulating layer 113 may be formed to surround the second portion 400b of the auxiliary electrode 400.

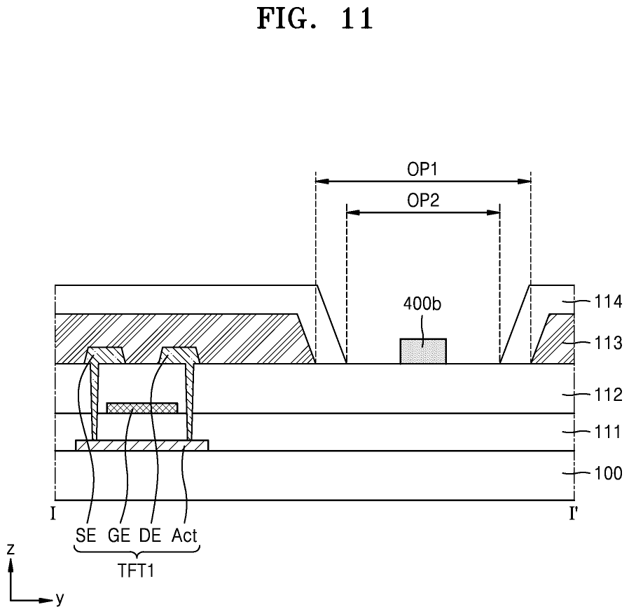

Referring to FIG. 11, the organic insulating layer 114 may be formed on the first inorganic insulating layer 113. The organic insulating layer 114 may include an organic insulating material, such as general-purpose polymers, such as PMMA and PS, polymer derivatives having a pheno-based group, acryl-based polymers, imide-based polymers, aryl ether-based polymers, amide-based polymers, fluorine-based polymers, p-xylene-based polymers, vinyl alcohol-based polymers, or any combinations thereof.

The second opening OP2, through which at least a portion of the second portion 400b of the auxiliary electrode 400 is exposed, may be defined in the organic insulating layer 114. In other words, the second portion 400b of the auxiliary electrode 400 may be disposed in the second opening OP2 of the organic insulating layer 114. The second opening OP2 of the organic insulating layer 114 may be formed to surround the second portion 400b of the auxiliary electrode 400. A size of the second opening OP2 of the organic insulating layer 114 may be less than a size of the first opening OP1 of the first inorganic insulating layer 113.

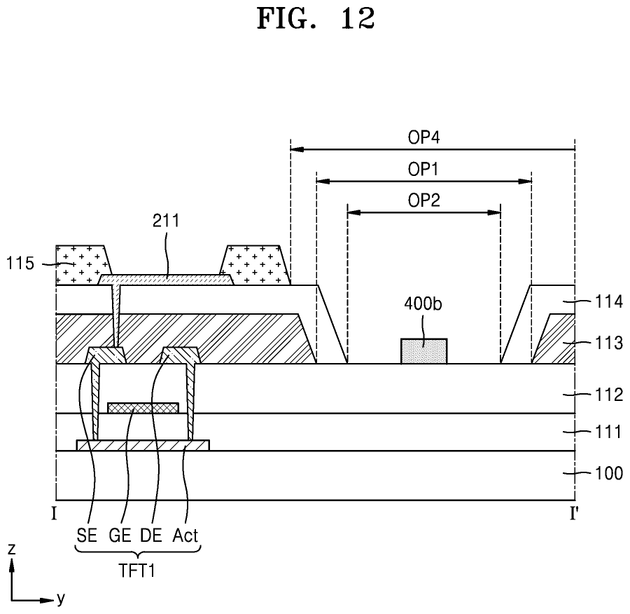

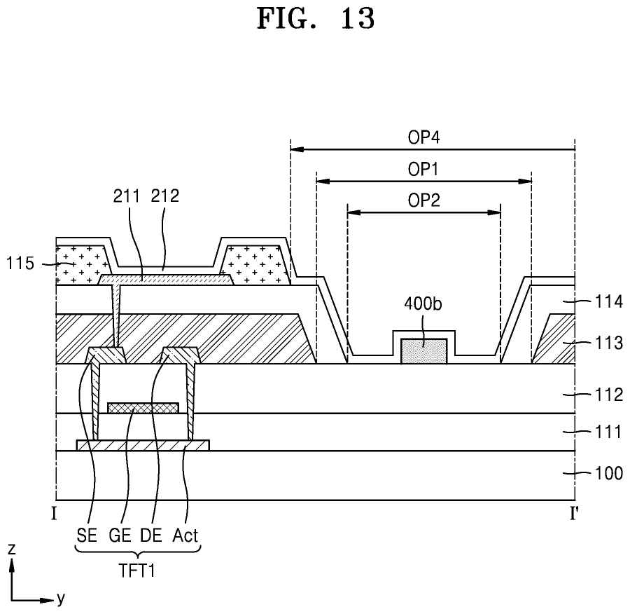

Referring to FIGS. 12 and 13, the pixel electrode 211 may be formed on the organic insulating layer 114, and the pixel-defining layer 115 exposing at least a portion of the pixel electrode 211 may be formed on the pixel electrode 211. On the pixel electrode 211, the intermediate layer 212 may be continuously formed on the substrate 100. An opening area of the pixel-defining layer 115, through which at least a portion of the pixel electrode 211 is exposed, may correspond to an emission area of the organic light-emitting diode OLED.

In an embodiment, the fourth opening OP4 may be defined in the pixel-defining layer 115. By the fourth opening OP4 of the pixel-defining layer 115, at least a portion of the second portion 400b of the auxiliary electrode 400 may be exposed. In other words, the second portion 400b of the auxiliary electrode 400 may be disposed in the fourth opening OP4 of the pixel-defining layer 115. The pixel-defining layer 115 may be formed to surround the second portion 400b of the auxiliary electrode 400.

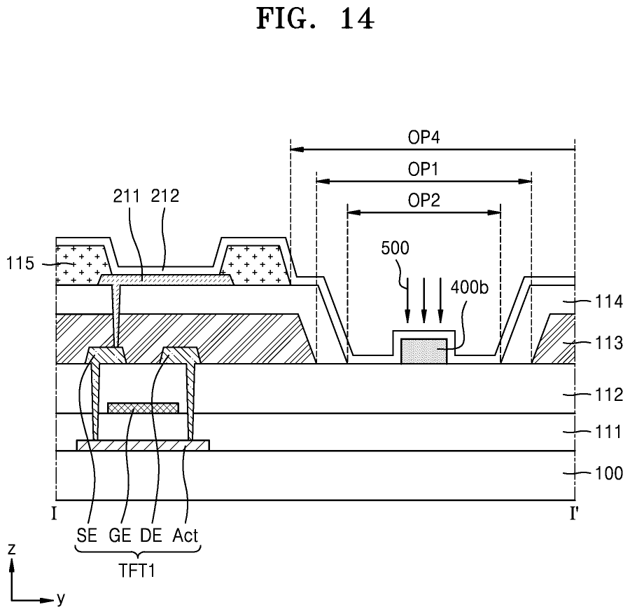

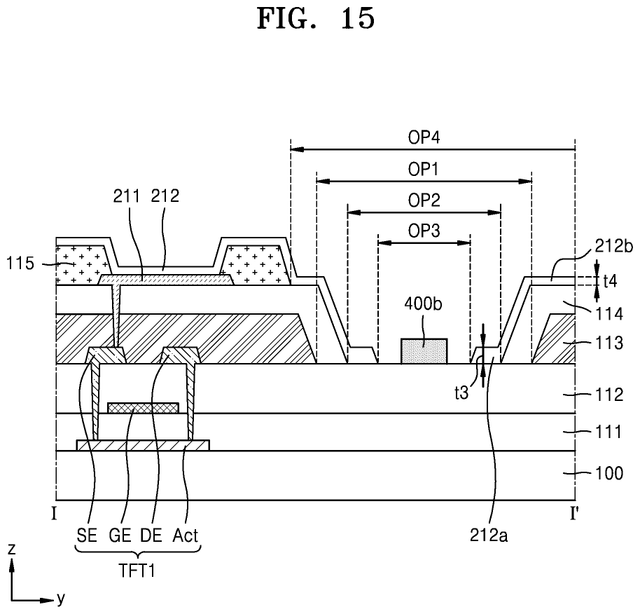

Referring to FIGS. 14 and 15, in order for the second portion 400b of the auxiliary electrode 400 to be exposed, a pulse voltage 500 may be applied to the second portion 400b of the auxiliary electrode 400. As shown in FIG. 7, because the second portion 400b of the auxiliary electrode 400 is relatively less than the first portion 400a of the auxiliary electrode 400 in terms of a thickness in the second direction (e.g., the y direction or the −y direction), when the pulse voltage 500 is applied, heat may be selectively generated due to Joule heating, and the sub-pixel may not be damaged. By the heat generated in the auxiliary electrode 400 by Joule heating, at least a portion of the intermediate layer 212 disposed on the second portion 400b of the auxiliary electrode 400 may be removed. In other words, by the heat generated in the auxiliary electrode 400 by Joule heating, the third opening OP3 exposing at least a portion of the second portion 400b of the auxiliary electrode 400 may be formed in the intermediate layer 212. Due to the heat generated in the second portion 400b of the auxiliary electrode 400, temperatures of the second portion 400b of the auxiliary electrode 400 and the intermediate layer 212 disposed thereon may be greater than or equal to about 300 degrees Celsius (° C.) and less than or equal to about 400° C.

A size of the third opening OP3 of the intermediate layer 212, the third opening OP3 exposing at least a portion of the second portion 400b of the auxiliary electrode 400, may be greater than a size of the area 400A in which the second portion 400b of the auxiliary electrode 400 is disposed. Due to the heat generated by applying the pulse voltage to the second portion 400b of the auxiliary electrode 400, at least a portion of the first portion 400a of the auxiliary electrode 400 as well as the second portion 400b of the auxiliary electrode 400 may be exposed. In other words, due to the heat generated by applying the pulse voltage 500 to the second portion 400b, not only the intermediate layer 212 disposed on the second portion 400b of the auxiliary electrode 400, but also the intermediate layer 212 disposed on the first portion 400a adjacent thereto may be removed. Because the second portion 400b and at least a portion of the first portion 400a of the auxiliary electrode 400 are exposed to contact the opposite electrode 213, an area of the auxiliary electrode 400 may be increased so that a voltage drop phenomenon of the display panel may be efficiently improved.

In an embodiment, a pulse width of the pulse voltage 500 may be greater than or equal to about 1 microsecond (μs) to less than or equal to about 10 μs. When the pulse width of the pulse voltage 500 is less than or equal to about 1 μs, heat sufficient to remove at least a portion of the intermediate layer 212 disposed on the second portion 400b of the auxiliary electrode 400 may not be generated. When the pulse width of the pulse voltage 500 is less than or equal to about 1 μs, at least the portion of the intermediate layer 212 disposed on the second portion 400b of the auxiliary electrode 400 may not be removed. When the pulse width of the pulse voltage 500 is greater than about 10 μs, heat generated in the second portion 400b of the auxiliary electrode 400 may spread to an area therearound, thus damaging the sub-pixel and adversely affecting a luminance and reliability of the display panel.

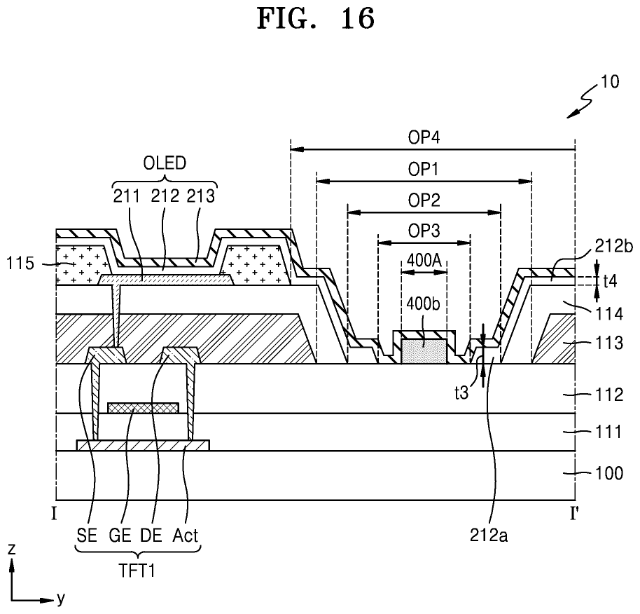

Referring to FIG. 16, the opposite electrode 213 may be formed on side and upper surfaces of the second portion 400b of the auxiliary electrode 400, the side and supper surfaces being exposed by the third opening OP3 of the intermediate layer 212. In other words, the opposite electrode 213 may be continuously formed on the substrate 100. By forming the opposite electrode 213 on the pixel electrode 211 and the intermediate layer 212, the organic light-emitting diode OLED may be formed on the first thin-film transistor TFT1.

Because the auxiliary electrode 400 is electrically connected to the common voltage supply lines 71, 73, and 75 (refer to FIG. 6) of the display panel 10 (refer to FIG. 6), the second portion 400b of the auxiliary electrode 400 and the opposite electrode 213 may be formed to contact each other, so that a distance between the common voltage ELVSS and the sub-pixel circuit PC (refer to FIG. 3) may be reduced. When the distance between the common voltage ELVSS and the sub-pixel circuit PC (refer to FIG. 3) is reduced, a voltage drop phenomenon in an active area of the display panel 10 may be improved, and the luminance of the display panel 10 may be improved.

Because the auxiliary electrode having an undercut shape is disposed to be spaced apart from the display panel and due to a difference in incidence angle between the intermediate layer and the opposite electrode, which are deposited on the auxiliary electrode having the undercut shape, when the opposite electrode and the auxiliary electrode contact each other, the difference in incidence angle when the intermediate layer and the opposite electrode is small. Thus, a degree of contact between the opposite electrode and the auxiliary electrode may be small, so that a voltage drop phenomenon of the display panel may not be efficiently improved.

In an embodiment, when heat is generated by applying the pulse voltage 500 to the second portion 400b of the auxiliary electrode 400, at least a portion of the intermediate layer 212 disposed on the second portion 400b of the auxiliary electrode 400 may be removed to expose the second portion 400b of the auxiliary electrode 400, so that the opposite electrode 213 may be disposed to contact the second portion 400b. Because the auxiliary electrode 400 is electrically connected to the common voltage supply line 70 of the display panel, a distance between the common voltage ELVSS and the sub-pixel circuit PC may be reduced, so that the voltage drop phenomenon in the active area of the display panel 10 and the luminance of the display panel may be improved.

According to embodiments configured as described above, a display device with improved reliability and quality and a method thereof may be implemented. However, the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a substrate;
a gate insulating layer disposed on the substrate;
an auxiliary electrode disposed on the gate insulating layer, extending in a first direction in a plane parallel to a main plane of the substrate, and including a first portion and a second portion, the first portion having a first thickness in a second direction crossing the first direction in the plane, and the second portion having a second thickness in the second direction;
an inorganic insulating layer disposed on the gate insulating layer and defining a first opening exposing at least a portion of the second portion of the auxiliary electrode;
an organic insulating layer disposed on the inorganic insulating layer and defining a second opening exposing at least a portion of the second portion of the auxiliary electrode;
an intermediate layer disposed on the organic insulating layer and defining a third opening exposing at least a portion of the second portion of the auxiliary electrode; and
an opposite electrode disposed on the intermediate layer and being in contact with upper and side surfaces of the auxiliary electrode,
wherein the second thickness of the second portion is less than the first thickness of the first portion.

2. The display device of claim 1, wherein an area of the third opening of the intermediate layer is greater than an area in which the auxiliary electrode is disposed.

3. The display device of claim 1, wherein a size of the first opening of the inorganic insulating layer is greater than a size of the second opening of the organic insulating layer.

4. The display device of claim 3, wherein the size of the second opening of the organic insulating layer is greater than a size of the third opening of the intermediate layer.

5. The display device of claim 1, further comprising a first thin-film transistor including a semiconductor layer disposed on the substrate, a gate electrode disposed on the semiconductor layer, and a source electrode and a drain electrode disposed on the gate electrode.

6. The display device of claim 1, further comprising an organic light-emitting diode including a pixel electrode disposed on the organic insulating layer, an intermediate layer disposed on the pixel electrode, and an opposite electrode disposed on the intermediate layer.

7. The display device of claim 6, further comprising a pixel-defining layer which is disposed on the pixel electrode and in which an opening exposing at least a portion of the pixel electrode is defined.

8. The display device of claim 7, wherein the pixel-defining layer defines a fourth opening, through which at least a portion of the second portion of the auxiliary electrode is exposed.

9. The display device of claim 8, wherein a size of the fourth opening of the pixel-defining layer is greater than each of a size of the second opening of the organic insulating layer and a size of the third opening of the intermediate layer.

10. The display device of claim 1, wherein the intermediate layer includes a third portion adjacent to the third opening, and a fourth portion spaced apart from the third opening, except for the third portion, and
a thickness of the third portion in a direction perpendicular to the main plane of the substrate is greater than a thickness of the fourth portion in a direction perpendicular to the main plane of the substrate.

11. A method of manufacturing a display device, the method comprising:
forming a gate insulating layer on a substrate;
forming an auxiliary electrode on the gate insulating layer, the auxiliary electrode extending in a first direction in a plane parallel to a main plane of the substrate, and including a first portion having a first thickness in a second direction crossing the first direction in the plane, and a second portion having a second thickness in the second direction;
forming an inorganic insulating layer on the gate insulating layer, the inorganic insulating layer defining a first opening which exposes at least a portion of the second portion of the auxiliary electrode;
forming an organic insulating layer on the inorganic insulating layer, the organic insulating layer defining a second opening which exposes at least a portion of the second portion of the auxiliary electrode;
forming an intermediate layer on the organic insulating layer, the intermediate layer defining a third opening which exposes at least a portion of the second portion of the auxiliary electrode; and
forming an opposite electrode on the intermediate layer, the opposite electrode being in contact with upper and side surfaces of the auxiliary electrode,
wherein the second thickness of the second portion is less than the first thickness of the first portion.

12. The method of claim 11, further comprising:
continuously forming the intermediate layer on the organic insulating layer and the auxiliary electrode;
generating heat by applying a pulse voltage to at least a portion of the second portion of the auxiliary electrode; and
defining the third opening exposing the second portion of the auxiliary electrode by removing, using the heat, at least a portion of the intermediate layer disposed on the upper and side surfaces of the auxiliary electrode.

13. The method of claim 12, wherein a pulse width of the pulse voltage is greater than or equal to about 1 microsecond and less than or equal to about 10 microseconds.

14. The method of claim 11, wherein an area of the third opening of the intermediate layer is greater than an area in which the auxiliary electrode is disposed.

15. The method of claim 11, wherein a size of the first opening of the inorganic insulating layer is greater than a size of the second opening of the organic insulating layer, and
the size of the second opening of the organic insulating layer is greater than a size of the third opening of the intermediate layer.

16. The method of claim 11, further comprising, before the forming the inorganic insulating layer, forming a first thin-film transistor including a semiconductor layer disposed on the substrate, a gate electrode disposed on the semiconductor layer, and a source electrode and a drain electrode disposed on the gate electrode.

17. The method of claim 11, further comprising, before the forming the intermediate layer:
forming a pixel electrode on the organic insulating layer; and
forming, on the pixel electrode, a pixel-defining layer in which an opening exposing at least a portion of the pixel electrode is defined.

18. The method of claim 17, wherein the pixel-defining layer defines a fourth opening, through which at least a portion of the second portion of the auxiliary electrode is exposed.

19. The method of claim 11, wherein the intermediate layer includes a third portion adjacent to the third opening, and a fourth opening spaced apart from the third opening, except for the third opening, and
a thickness of the third portion in a direction perpendicular to the main plane of the substrate is greater than a thickness of the fourth portion in a direction perpendicular to the main plane of the substrate.

20. The method of claim 17, further comprising forming an opposite electrode on the intermediate layer.
